(19) United States
(12) Patent Application Publication
(10) Pub. No.: US 2012/0187522 A1
(43) Pub. Date: Jul. 26, 2012

(54) STRUCTURE AND METHOD FOR REDUCTION OF VT-W EFFECT IN HIGH-K METAL GATE DEVICES

(75) Inventors: Michael V. Aquilino, Hopewell Junction, NY (US); Christopher V. Baiocco, Newburgh, NY (US); Richard A. Conti, Katonach, NY (US); Daniel J. Jaeger, Wappingers Falls, NY (US); Vijay Narayanan, New York, NY (US)

(73) Assignee: INTERNATIONAL BUSINESS MACHINES CORPORATION, ARMONK, NY (US)

(21) Appl. No.: 13/010,041

(22) Filed: Jan. 20, 2011

(51) Int. Cl. H01L 29/06; G06F 17/50; H01L 21/762

(52) U.S. Cl. 257/506; 438/424; 716/100; 257/E21.546; 257/E29.006

(57) ABSTRACT

A substrate is provided. An STI trench is formed in the substrate. A fill material is formed in the STI trench and then planarized. The substrate is exposed to an oxidizing ambient, growing a liner at a bottom and sidewalls of the STI trench. The liner reduces the Vt-W effect in high-k metal gate devices.

### BACKGROUND OF THE INVENTION

The present invention relates generally to a semiconductor device and method of forming the same and, more specifically, to reducing the Vt-W effect in high-k metal gate devices.

When hafnium oxide (HfO2) or hafnium silicon oxynitride (HfSiON) is used as a gate dielectric in high-k metal gate devices, threshold voltage (Vt) as a function of decreasing device width shows a significant increase in nFET Vt and a decrease in pFET Vt (Vt-W effect). In addition, interfacial oxide regrowth increases as the device width decreases (Ig ratio). These are indicative of oxygen ingress over the shallow trench isolation (STI).

### SUMMARY OF THE INVENTION

In a first aspect of the invention, a method of forming a device includes providing a substrate. The method includes forming an STI trench in the substrate. The method includes forming a fill material in the STI trench. The method further includes planarizing the fill material. The method also includes exposing the substrate to an oxidizing ambient, wherein a liner is grown at a bottom and sidewalls of the STI trench.

In a further aspect of the invention, a method of forming a device includes providing a substrate. The method includes forming an STI trench in the substrate. The method includes forming a first liner on a bottom and sidewalls of the STI trench. The method includes forming an insulating material on the first liner to fill the STI trench. The method further includes planarizing the insulating material. The method also includes exposing the substrate to an oxidizing ambient, wherein a second liner is grown at a bottom and sidewalls of the trench.

In a further aspect of the invention a device includes a substrate. The device includes an STI trench formed in the substrate. The device further includes a fill material formed in the STI trench, wherein a top surface of the fill material is coplanar with a top surface of the substrate. The device also includes a liner grown at a bottom and sidewalls of the STI trench.

In a yet further aspect of the invention, a design structure tangibly embodied in a machine readable medium for designing, manufacturing, or testing an integrated circuit, the design structure includes a substrate. The design structure includes an STI trench formed in the substrate. The design structure further includes a fill material formed in the STI trench, wherein a top surface of the fill material is coplanar with a top surface of the substrate. The design structure also includes a liner grown at a bottom and sidewalls of the STI trench.

### BRIEF DESCRIPTION OF THE DRAWINGS

The present invention is described in the detailed description below, in reference to the accompanying drawings that depict non-limiting examples of exemplary embodiments of the present invention.

FIG. 1 shows a starting structure and processing steps in accordance with an embodiment of the invention;

FIG. 2 shows a structure having an STI liner in accordance with an embodiment of the invention;

FIG. 3 shows processing steps and intermediate structures in accordance with an embodiment of the invention;

FIG. 4 shows processing steps and a final structure in accordance with an embodiment of the invention; and

FIG. 5 shows a block diagram of an exemplary design flow used in semiconductor design, manufacturing, and/or test.

### DETAILED DESCRIPTION OF THE INVENTION

Disclosed herein is a structure and method of shallow trench isolation (STI) late liner for reduction of Vt-W effect in high-k metal gate devices. By introducing an oxidizing anneal after the STI chemical mechanical polish (CMP) process, the STI fill is densified and stabilized such that oxygen transport through the STI is reduced and Vt-W effect mitigated.

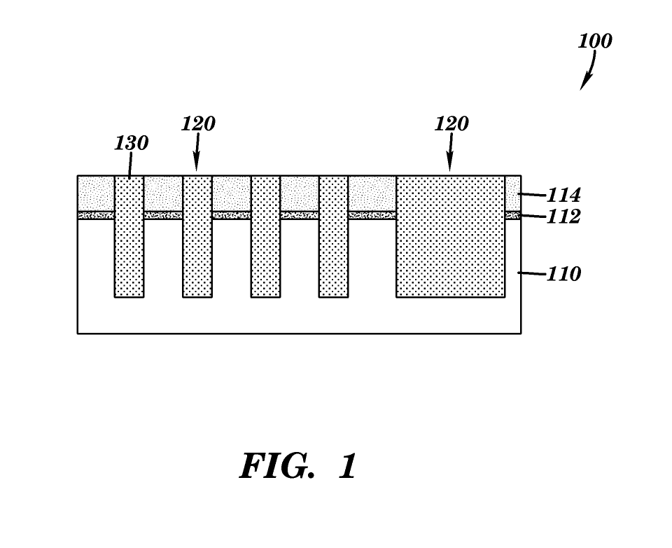

FIG. 1 shows a starting structure and processing steps in accordance with an embodiment of the invention. Starting wafer structure 100 includes a substrate 110. Substrate 110 may be a bulk semiconductor substrate, such as silicon, germanium or silicon germanium, a semiconductor-on-insulator (SOI) or other materials or combinations of materials. A conventional pad oxide layer 112 is deposited on top of substrate 110. A conventional pad nitride layer 114 such as silicon nitride (SiN) is also deposited on top of substrate 110 to protect active regions of the devices. STI trenches 120 are formed in substrate 110 using conventional etching processes such as RIE. STI trenches 120 have a depth in a range from about 2000 angstroms to about 4000 angstroms, but can be shallower or deeper. STI trenches 120 are filled with STI fill material 130. STI fill material 130 may be an insulator such as silicon dioxide (SiO2) or other materials or combinations of materials. STI fill may be formed in trenches 120 by using conventional methods such as TEOS ozone sub atmospheric or atmospheric pressure deposition, high density plasma, application of a spin-on-glass, use of a flow-fill or condensation chemical vapor deposition (CVD) oxide or any other known or later developed methods. STI fill material 130 is planarized using conventional processes such as a CMP process.

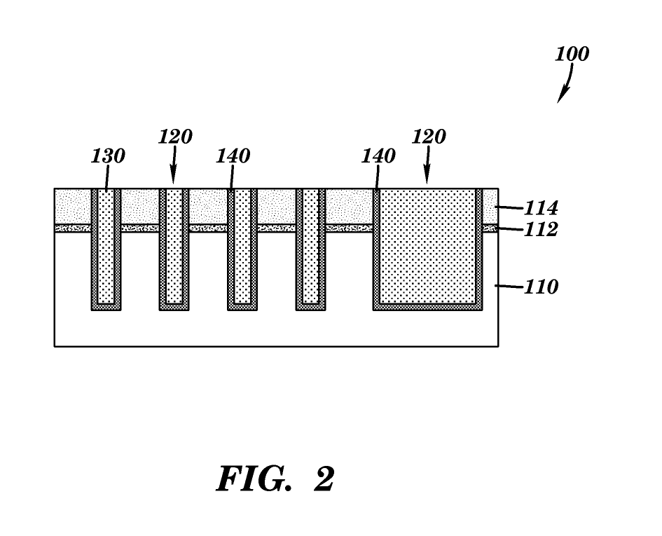

Optionally, as shown in FIG. 2, an STI liner 140 may be grown on a bottom and sidewalls of STI trenches 120. STI liner 140 may be grown using conventional methods such as furnace oxide, in-situ steam generation (ISSG) RADOX oxide, oxide with nitridation, sacrificial oxidation, strip and regrowth or any other known or later developed methods. STI liner 140 may comprise silicon oxynitride (SiON) or other materials or combinations of materials. STI liner 140 may have a thickness in a range from about 20 angstroms to about 30 angstroms, but can be thinner or thicker.

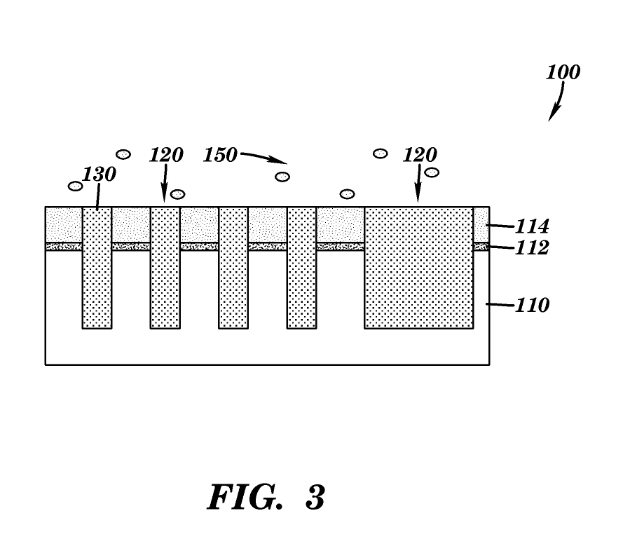

Referring to FIG. 3, substrate 110 is exposed to an oxidizing ambient 150. The oxidizing ambient may comprise oxygen (O2), wet oxygen (O2), nitrous oxide (N2O) and oxygen (O2) or other materials or combination of materials. Oxygen is diffused to a bottom of dense and isolated trenches. The late liner oxidation is performed after planarization of STI fill material 130. Dense areas of STI fill material 130 may have upwards of double thickness due to conformal fill material properties. This allows oxygen transport uniformly throughout the STI. The oxidation of the film acts to densify and stabilize the STI from oxygen outgassing and external oxygen transport that could migrate into the devices during subsequent processing. Late liner oxidation process conditions may be in the range of about 800 degrees Celsius to about 1000 degrees Celsius in oxygen (O2) at about 1 atm pressure and about 5 SLM to about 10 SLM (liter/minute) flows of oxygen (O2), hydrogen (H2) or nitrous oxide (N2O) gas. The late liner oxidation may grow a bare silicon wafer oxide equivalent of about 100 angstroms, but can be thinner or thicker, to sufficiently reduce the Vt-W effect. Utilizing a wet oxygen (O2) or a nitrous oxide (N2O) plus oxygen (O2) ambient provides a barrier against latter sources of oxidation.

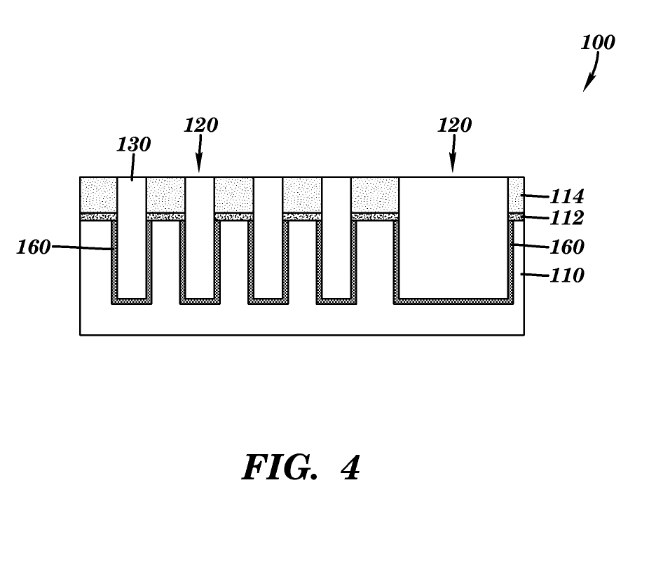

Referring to FIG. 4, as a result of the late liner oxidation, a liner 160 is grown at a bottom and sidewalls of STI trenches 120. Liner 160 may have a thickness in a range from about 25 angstroms to about 50 angstroms, but can be thinner or thicker. Liner 160 may comprise an oxide if an oxygen (O2) oxidizing ambient is used or oxynitride if a nitrogen (N2) oxidizing ambient is used. A conventional high temperature nitrogen (N2) based anneal may be performed for further densification and wet etch rate reduction. The N2 based ambient alone is not sufficient to modulate the Vt-W effect. Conventional processes maybe used to form high-k metal gate devices, including removing the SiN pad layer from the wafer.

The following Table 1 shows a reduction in nFET and pFET Vt-W by the late liner oxidation in accordance with an embodiment of the invention. A major feature of a low power microprocessor is that the transistors have ultra low leakages so the battery life in a product is extended for as long as possible. This invention will allow acceptable performance and low power for high-k metal gate based technology by reducing the Vt-W effect in high-k metal gate transistors, enabling low power devices.

TABLE 1

| | | No late liner | Late liner |
|---|---|---|---|
| nFET | Vt-W (mV) | 150 | 75 |
| pFET | Vt-W (mV) | −20 | −15 |

### Design Structure

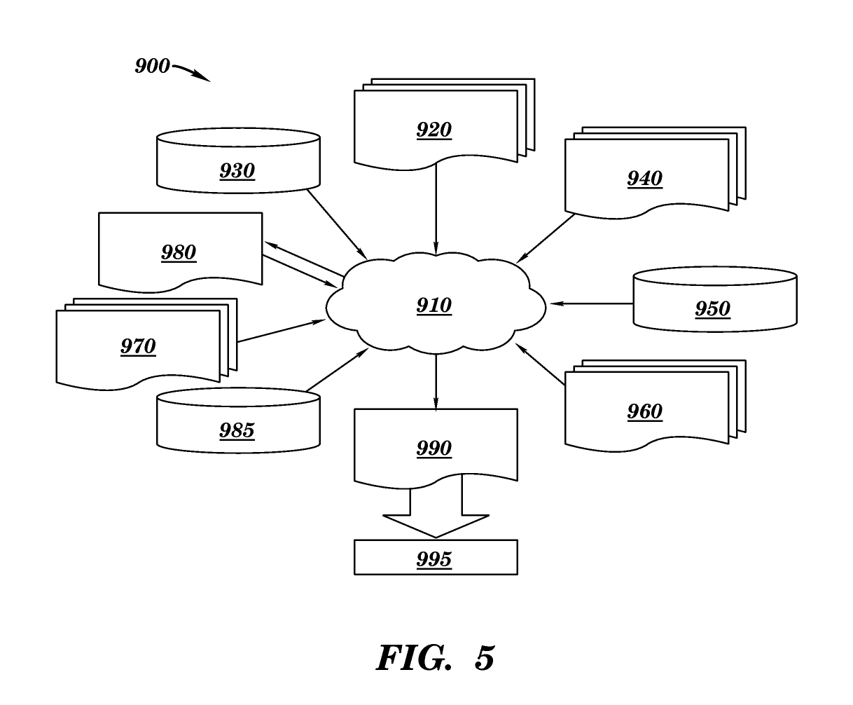

FIG. 5 shows a block diagram of an exemplary design flow 900 used for example, in semiconductor design, manufacturing, and/or test. Design flow 900 may vary depending on the type of IC being designed. For example, a design flow 900 for building an application specific IC (ASIC) may differ from a design flow 900 for designing a standard component or from a design flow 900 for instantiating the design into a programmable array, for example a programmable gate array (PGA) or a field programmable gate array (FPGA) offered by Alter® Inc. or Xilinx® Inc. Design structure 920 is preferably an input to a design process 910 and may come from an IP provider, a core developer, or other design company or may be generated by the operator of the design flow, or from other sources. Design structure 920 comprises an embodiment of the invention as shown in FIGS. 1-4 in the form of schematics or HDL, a hardware-description language (e.g., Virology, VHDL, C, etc.). Design structure 920 may be contained on one or more machine-readable media. For example, design structure 920 may be a text file or a graphical representation of an embodiment of the invention as shown in FIGS. 1-4. Design process 910 preferably synthesizes (or translates) embodiments of the invention as shown in FIGS. 1-4 into a net list 980, where net list 980 is, for example, a list of wires, transistors, logic gates, control circuits, I/O, models, etc. that describes the connections to other elements and circuits in an integrated circuit design and recorded on at least one of machine readable media. For example, the medium may be a CD, a compact flash, other flash memory, a packet of data to be sent via the Internet, or other networking suitable means. The synthesis may be an iterative process in which net list 980 is resynthesized one or more times depending on design specifications and parameters for the circuit.

Design process 910 may include using a variety of inputs; for example, inputs from library elements 930 which may house a set of commonly used elements, circuits, and devices, including models, layouts, and symbolic representations, for a given manufacturing technology (e.g., different technology nodes, 32 nm, 45 nm, 90 nm, etc.), design specifications 940, characterization data 950, verification data 960, design rules 970, and test data files 985 (which may include test patterns and other testing information). Design process 910 may further include, for example, standard circuit design processes such as timing analysis, verification, design rule checking, place and route operations, etc. One of ordinary skill in the art of integrated circuit design can appreciate the extent of possible electronic design automation tools and applications used in design process 910 without deviating from the scope and spirit of the invention. The design structure of the invention is not limited to any specific design flow.

Design process 910 preferably translates an embodiment of the invention as shown in FIGS. 1-4, along with any additional integrated circuit design or data (if applicable), into a second design structure 990. Design structure 990 resides on a storage medium in a data format used for the exchange of layout data of integrated circuits and/or symbolic data format (e.g. information stored in a GDSII (GDS2), GL1, OASIS, map files, or any other suitable format for storing such design structures). Design structure 990 may comprise information such as, for example, symbolic data, map files, test data files, design content files, manufacturing data, layout parameters, wires, levels of metal, vias, shapes, data for routing through the manufacturing line, and any other data required by a semiconductor manufacturer to produce embodiments of the invention as shown in FIGS. 1-4. Design structure 990 may then proceed to a stage 995 where, for example, design structure 990: proceeds to tape-out, is released to manufacturing, is released to a mask house, is sent to another design house, is sent back to the customer, etc.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A method of forming a device, comprising;
providing a substrate;
forming an STI trench in the substrate;
forming a fill material in the STI trench;
planarizing the fill material; and
exposing the substrate to an oxidizing ambient, wherein a liner is grown at a bottom and sidewalls of the STI trench.

2. The method according to claim 1, wherein the STI trench has a depth in a range from about 2000 angstroms to about 4000 angstroms.

3. The method according to claim 1, wherein the fill material is formed by chemical vapor deposition (CVD).

4. The method according to claim 1, wherein the fill material comprises silicon dioxide (SiO2).

5. The method according to claim 1, wherein the planarizing the fill material step comprises performing a chemical mechanical polishing (CMP).

6. The method according to claim 1, wherein the oxidizing ambient comprises oxygen (O2).

7. The method according to claim 6, wherein the liner comprises oxide.

8. The method according to claim 1, wherein the oxidizing ambient comprises nitrous oxide (N2O).

9. The method according to claim 8, wherein the liner comprises oxynitride.

10. The method according to claim 1, wherein the liner has a thickness in a range from about 25 angstroms to about 50 angstroms.

11. The method according to claim 1, further comprising performing a high temperature nitrogen (N2) based anneal.

12. A method of forming a device, comprising;
providing a substrate;
forming an STI trench in the substrate;
forming a first liner on a bottom and sidewalls of the STI trench;
forming an insulating material on the first liner to fill the STI trench;
planarizing the insulating material; and
exposing the substrate to an oxidizing ambient, wherein a second liner is grown at a bottom and sidewalls of the trench.

13. The method according to claim 12, wherein the first liner comprises silicon oxynitride (SiON)

14. The method according to claim 13, wherein the liner has a thickness of in a range from about 20 angstroms to about 30 angstroms.

15. The method according to claim 12, wherein the second liner comprises one of oxide and oxynitride.

16. The method according to claim 12, wherein the second liner has a thickness in a range from about 25 angstroms to about 50 angstroms.

17. A device, comprising:
a substrate;
an STI trench formed in the substrate;
a fill material formed in the STI trench, wherein a top surface of the fill material is coplanar with a top surface of the substrate; and
a liner grown at a bottom and sidewalls of the STI trench.

18. The device according to claim 17, wherein the liner comprises oxide.

19. The device according to claim 17, wherein the liner comprises oxynitride.

20. The device according to claim 17, wherein the liner has a thickness in a range from about 25 angstroms to about 50 angstroms.

21. A design structure tangibly embodied in a machine readable medium for designing, manufacturing, or testing an integrated circuit, the design structure comprising:
a substrate;
an STI trench formed in the substrate;
a fill material formed in the STI trench, wherein a top surface of the fill material is coplanar with a top surface of the substrate; and
a liner grown at a bottom and sidewalls of the STI trench.

22. The design structure according to claim 21, wherein the liner comprises oxide.

23. The design structure according to claim 21, wherein the liner comprises oxynitride.

24. The design structure according to claim 21, wherein the liner has a thickness in a range from about 25 angstroms to about 50 angstroms.

25. The design structure of claim 21, wherein the design structure is synthesized into a netlist.
